(19) United States
(12) Patent Application Publication
(10) Pub. No.: US 2014/0103439 A1
(43) Pub. Date: Apr. 17, 2014

(54) Transistor Device and Method for Producing a Transistor Device

(71) Applicant: INFINEON TECHNOLOGIES DRESDEN GMBH, Dresden (DE)

(72) Inventor: Rolf Weis, Dresden (DE)

(21) Appl. No.: 13/651,603

(22) Filed: Oct. 15, 2012

(51) Int. Cl. H01L 29/78; H01L 29/66

(52) U.S. Cl. CPC H01L 29/7855; H01L 29/66795
USPC 257/365; 438/283

(57) ABSTRACT

A transistor device includes at least one transistor cell. The at least one transistor cell includes a semiconductor fin, and a source region, a drain region, a drift region and a body region in the semiconductor fin. The body region is arranged adjacent the source region and the drift region in a first direction of the semiconductor fin. The source region is arranged adjacent the drift region in a second direction of the semiconductor fin and dielectrically insulated from the drift region by a dielectric layer. The drift region is arranged adjacent the drain region in the first direction and has a doping concentration lower than a doping concentration of the drain region. A gate electrode is adjacent the body region in a third direction of the semiconductor fin.

### TECHNICAL FIELD

Embodiments of the present invention relate to a transistor device, in particular a transistor device having an active device integrated in a semiconductor fin, and to a method for producing a transistor device.

### BACKGROUND

A FINFET is a relatively new type of field-effect transistor device that includes a body region located in a thin semiconductor fin. Conventional FINFETs are employed in logic devices, such as microprocessors, and have a voltage blocking capability of several volts. One approach to obtain a semiconductor device with a higher voltage blocking capability is to connect a plurality of FINFETs in series and to commonly switch on or off the FINFETs of the series circuit.

Nevertheless, there is a need to provide a transistor device with a semiconductor fin having a higher voltage blocking capability than several volts.

### SUMMARY

A first embodiment relates to a transistor device including at least one transistor cell. The at least one transistor cell includes a semiconductor fin, and a source region, a drain region, a drift region and a body region in the semiconductor fin. The body region is arranged adjacent the source region and the drift region in a first direction of the semiconductor fin, the source region is arranged adjacent the drift region in a second direction of the semiconductor fin and is dielectrically insulated from the drift region by a dielectric layer, and the drift region is arranged adjacent the drain region in the first direction and has a doping concentration lower than a doping concentration of the drain region. A gate electrode is adjacent the body region in a third direction of the semiconductor fin.

A second embodiment relates to a method for producing a transistor device. The method includes providing a semiconductor body including at least one semiconductor fin. The at least one semiconductor fin includes a drift region and a body region adjoining the drift region in a first direction of the semiconductor fin. The method further includes forming at least two trenches that are distant in a second direction of the semiconductor fin and that each extend through the drift region to or into the body region, forming a gate electrode adjacent the body region on at least one side of the semiconductor fin, forming dielectric layers in the at least two trenches, removing the drift region between the at least two trenches and forming a source region between the at least two trenches, and forming a drain region in remaining sections of the drift region and in the region of a surface of the semiconductor fin.

Those skilled in the art will recognize additional features and advantages upon reading the following detailed description, and upon viewing the accompanying drawings.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 (that includes FIGS. 1A to 1F) illustrates one transistor cell of a transistor device according to a first embodiment;

FIG. 2 illustrates one transistor cell of a transistor device according to a second embodiment;

FIG. 3 illustrates one transistor cell of a transistor device according to a third embodiment;

FIG. 4 illustrates one transistor cell of a transistor device according to a fourth embodiment;

FIG. 5 illustrates one transistor cell of a transistor device according to a fifth embodiment;

FIG. 6 illustrates a vertical cross-sectional view of a transistor device including a plurality of transistor cells according to a first embodiment;

FIG. 7 illustrates a vertical cross-sectional view of a transistor device including a plurality of transistor cells according to a second embodiment;

FIG. 8 illustrates a top view of a transistor device including a plurality of transistor cells according to a further embodiment;

FIG. 9 (that includes FIGS. 9A to 9H) illustrates one embodiment of a method for producing a transistor device;

FIG. 10 (that includes FIGS. 10A and 10B) illustrates vertical cross-sectional views of a transistor device including a substrate;

FIG. 11 illustrates one embodiment of the substrate; and

FIG. 12 illustrates a further embodiment of the substrate.

### DETAILED DESCRIPTION

In the following detailed description, reference is made to the accompanying drawings, which form a part thereof, and in which specific embodiments in which the invention may be practiced are illustrated.

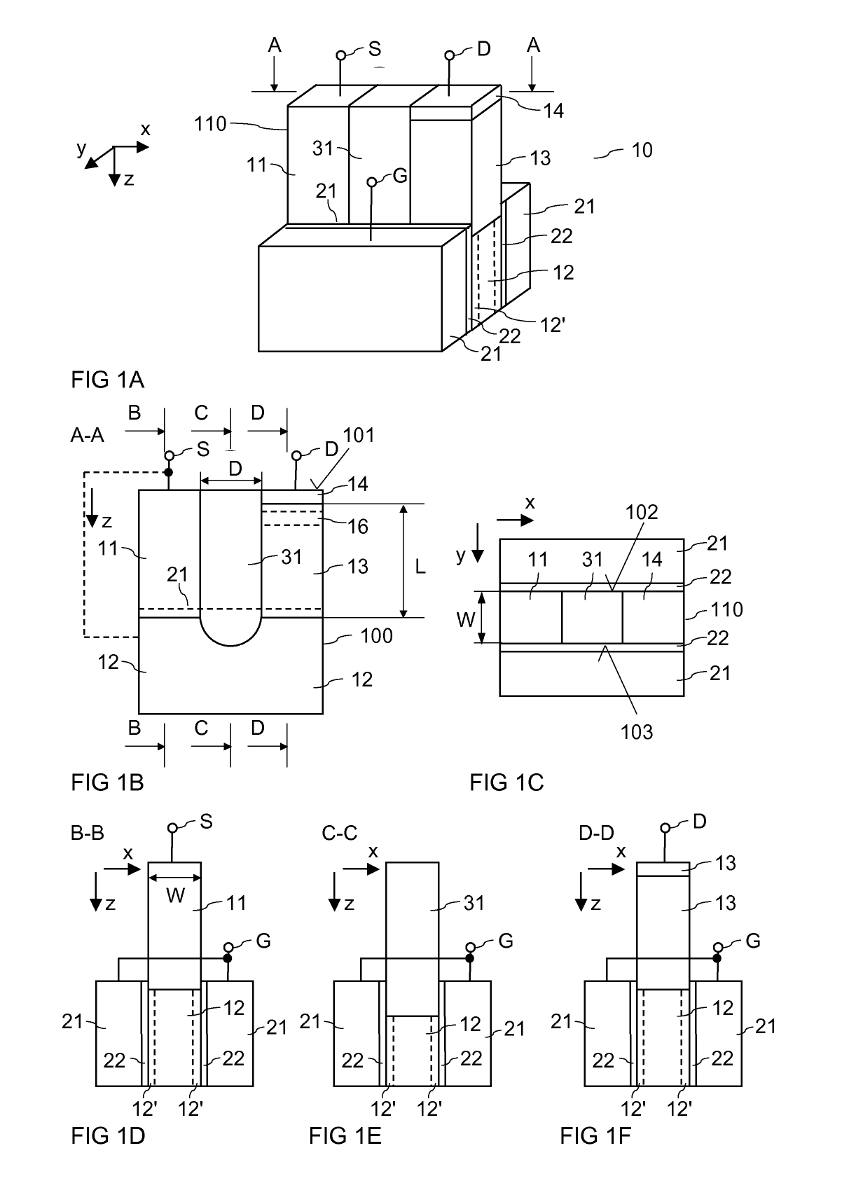

FIGS. 1A to 1F illustrate one transistor cell 10 of a transistor device that includes at least one transistor cell. FIGS. 1A to 1F show different views of the transistor cell 10. FIG. 1A shows a perspective view of the transistor cell, FIG. 1B shows a vertical cross-sectional view of the transistor cell in a first section plane A-A, FIG. 1C shows a top view on the transistor cell, FIG. 1D shows a vertical cross-sectional view of the transistor cell 10 in a second vertical section plane B-B, FIG. 1E shows a vertical cross-sectional view of the transistor cell 10 in a third vertical section plane C-C, and FIG. 1F shows a fourth vertical cross-sectional view of the transistor cell 10 in a fourth vertical section plane D-D.

Referring to FIGS. 1A to 1C, the transistor cell 10 includes a semiconductor fin 110. In the semiconductor fin 110, the transistor device includes a source region 11, a body region 12, a drift region 13 and a drain region 14. The semiconductor fin 110 may include a conventional semiconductor material, such as silicon (Si), silicon carbide (SiC), gallium arsenide (GaAs), gallium nitride (GaN), or the like.

Referring to FIG. 1B, that shows a vertical cross-sectional view of the semiconductor fin 110 in the first section plane A-A, the body region 12 is adjacent to both the source region 11 and the drift region 13 in a first direction z of the semiconductor fin 110, and adjoins the source region 11 and the drift region 13 in the present embodiment. The first direction z will be referred to as vertical direction of the semiconductor fin 110 in the following. The source region 11 is electrically connected to a source terminal S (that is only schematically illustrated in FIG. 1B) and may extend to a first surface 101 (top surface) of the semiconductor fin 110. The drift region 13 is coupled to the drain region 14 on a side facing away from the body region 12. In the embodiment of FIG. 1B, the drift region 13 adjoins the drain region 14. According to a further embodiment (illustrated in dashed lines in FIG. 1B) a field stop region 16 of the same doping type as the drift region 13, but more highly doped than the drift region 13, is arranged between the drift region 13 and the drain region 14. The drain region 14 is connected to a drain terminal D (that is schematically illustrated in FIG. 1B) and may extend to the first surface 101 of the semiconductor fin 110.

Referring to FIGS. 1A and 1B, the source region 11 and the drift region 13 are distant in a second direction x of the semiconductor fin 110, and are dielectrically insulated from each other by a dielectric layer 31. The second direction x of the semiconductor fin 110 will be referred to as first lateral direction in the following. The dielectric layer 31 is arranged in a trench between the source region 11 and the drift region 13. The trench with the dielectric layer 31 extends to or into (as illustrated) the body region 12 in the vertical direction, so as to separate the source region 11 from the drift region 13. Further, the dielectric layer 31, referring to FIG. 1C, extends from a first sidewall 102 to a second sidewall 103 of the semiconductor fin 110. Referring to FIG. 1B, the trench with the dielectric layer 31 may basically have a U-shape.

Referring to FIGS. 1A to 1F, the transistor cell further includes a gate electrode 21 that is adjacent the body region 12 in a third direction y of the semiconductor fin 110. The third direction y will be referred to as second lateral direction in the following. In the present embodiment, the gate electrode 21 is adjacent the body region 12 on both the first and second sidewalls 102, 103 of the semiconductor fin 110. The gate electrode 21 is electrically connected to a gate terminal G (that is only schematically illustrated in the figures). In the embodiment of FIGS. 1A to 1F, the transistor device is implemented as an MOS transistor device. In this case, the gate electrode 21 is dielectrically insulated from the body region 12 (and from the source and drift regions 11, 13) by a gate dielectric 22. The gate electrode 21 may include a conventional gate electrode material such as a metal or a highly doped polycrystalline semiconductor material. The gate dielectric 22 may include a conventional gate dielectric material such as an oxide.

The transistor device of FIGS. 1A to 1F can be implemented as a normally-on transistor (depletion transistor). In this case, the drain region 14, the drift region 13 and the source region 11 have the same doping type. The body region 12 either has the same doping type as the source region 11, the drift region 13 and the drain region 14, or has a doping type complementary to the source region 11, the drift region 13 and the drain region 14 and includes at least one channel region 12′ (illustrated in dashed lines in FIGS. 1A and 1D to 1F) of the same doping type as the source region 11, the drift region 13 and the drain region 14 along the gate dielectric 22. The at least one channel region 12′ extends between the source region 11 and the drift region 13 along the gate dielectric 22. The depletion transistor device can be implemented as an n-type transistor device or as a p-type transistor device. In an n-type transistor device, the source region 11, the drift region 13, the drain region 14 and at least the channel region 12′ of the body region 12 are n-doped, while in a p-type transistor device these device regions are p-doped.

Especially when the body region 12 is doped complementary to the source region 11, the source terminal may be connected to the body region 12 (as illustrated in dashed lines in FIG. 1B). In this case a pn junction between the body region 12 and the drift region 11 forms an internal diode (body diode) between the drain and source terminals D, S of the transistor device.

The transistor device, when implemented as a depletion MOS transistor device, can be operated like a conventional depletion MOS transistor device. That is, the transistor device is in an on-state and conducts a current between the source terminal S and the drain terminal D, when a voltage is applied between the source and drain terminals S, D and when a drive voltage is applied between the gate terminal G and the source terminal S that does not pinch off a conducting channel in the body region 12 between the source region 11 and the drift region 13. In an n-type depletion MOSFET, the conducting channel is pinched off, when the drive voltage is below a negative pinch-off voltage. The absolute value of the pinch-off voltage is dependent on the doping concentration of the body region 12 or the channel regions 12′, respectively. When the body region 12 completely has the same doping type as the source region 11, the pinch-off voltage is further dependent on the thickness of the semiconductor fin 110. The thickness of the semiconductor fin 110 is the dimension of the semiconductor fin 110 in the second lateral direction y. According to one embodiment, the thickness of the semiconductor fin 110 is between 5 nanometres (nm) and 100 nanometres.

According to a further embodiment, the transistor device is implemented as a normally-off (enhancement) transistor device, in particular an enhancement MOS transistor. In this case, the body region 12 is completely doped complementarily to the source region 11 and the drift region 13. The transistor device can be implemented as a MOSFET or as an IGBT. In a MOSFET, the drain region 14 has the same doping type as the drift region 13, while in an IGBT the drain region 14 has a doping type that is complementary to the doping type of the drift region 13. Further, the normally-off MOS transistor can be implemented as an n-type transistor device or as p-type transistor device. In an n-type transistor device the source region 11 and the drift region 13 are n-doped, while the body region 12 is p-doped. In a p-type transistor device, the source region 11 and the drift region 13 are p-doped, while the body region 12 is n-doped.

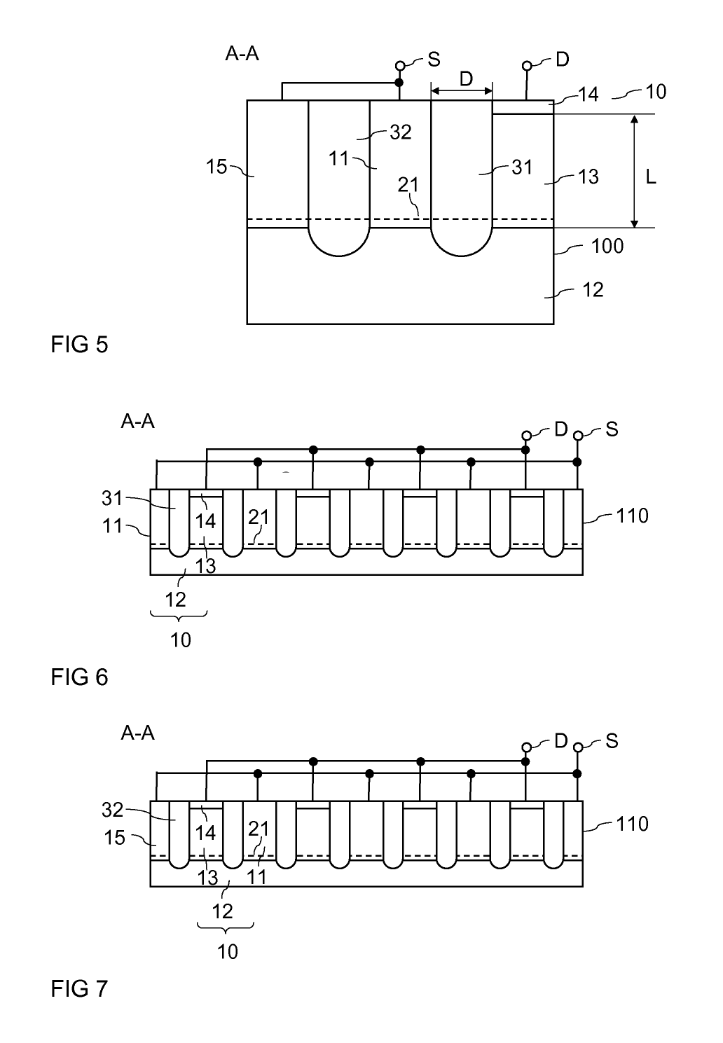

The operating principle of a transistor device implemented as a normally-off transistor device is explained with reference to an n-type MOSFET below. The operating principle explained in the following applies to an IGBT or to a p-type enhancement MOSFET accordingly. In a p-type device the polarities of the voltages explained in the following have to be inverted. For explanation purposes it is further assumed that the body region 12 is electrically connected to the source terminal S. One way of connecting the source terminal S to the body region 12 is explained with reference to FIG. 5 below.

Like a conventional MOSFET, the MOSFET of FIGS. 1A to 1F, when implemented as an n-type enhancement MOSFET, is in an on-state, when a voltage (a positive voltage) is applied between the drain and source terminals D, S and when a drive voltage is applied between the gate and source terminals G, S that generates a conducting channel in the body region 12 along the gate dielectric 22 between the source region 11 and the drift region 13. A drive voltage causing a conducting channel in the body region 12 is a voltage above a threshold voltage of the transistor device. In an n-type enhancement MOSFET, the threshold voltage is a positive gate-source voltage. The magnitude of the threshold voltage is, inter alia, dependent on the doping concentration of the body region 12. This is commonly known so that no further explanations are required in this regard. The enhancement MOSFET is in an off-state, when a voltage (a positive voltage) is applied between the drain and source terminals D, S, and when the drive voltage is below the threshold voltage so that the conducting channel in the body region 12 is interrupted. The voltage applied between the drain and source terminals D, S reverse biases a pn-junction that is formed between the drift region 13 (that is an n-type region in an n-type enhancement MOSFET) and the body region 12 (that is a p-type region in an n-type enhancement MOSFET). The positive voltage between the drain and source terminals, D, S reverse biases the pn-junction.

When the pn-junction is reverse-biased a depletion region (space charge region) expands in the drift region 13 beginning at the pn-junction. The width of the depletion region, which is a dimension of the depletion region in a direction perpendicular to pn-junction, is dependent on the voltage that reverse biases the pn-junction; the width of the depletion region increases when the reverse biasing voltage (the voltage between the drain and source terminals D, S) increases. Within the depletion region there are ionized dopant atoms in the drift region 13. These ionized dopant atoms have a positive charge when the drift region 13 is n-doped (and have a negative charge when the drift region is p-doped). Negative charges corresponding to the positive charges in the drift region 13 are located in the body region 12 on the other side of the pn-junction. However, not only the body region 12, but also the source region 11, that has a negative potential relative to the electrical potential of the drift region when the pn-junction is reverse biased, provides negative charges (counter charges) corresponding to positive charges in the drift region 13.

The voltage blocking capability of the semiconductor device is reached when the electrical field generated by ionized dopant atoms in the drift region 13 and corresponding counter charges in the body region 12 reaches the critical electrical field. The critical electrical field is a material constant of the semiconductor material of the semiconductor fin 110. The reverse biasing voltage at which the critical electrical field is reached at the pn-junction 12 is dependent on the doping concentration of the drift region 13 and is, therefore, dependent on the number of dopant atoms that can be ionized when a reverse biasing voltage is applied to the pn-junction. When, however, like in the transistor device of FIGS. 1A to 1F, ionized dopant atoms in the drift region 13 find corresponding counter charges not only in the body region 12 on the other side of the pn-junction but also adjacent the drift region 13, namely in the source region 11, the doping concentration of the drift region 13 can be increased without decreasing the voltage blocking capability of the semiconductor device. Increasing the doping concentration of the drift region 13 is beneficial concerning the on-resistance of the transistor device. In a unipolar semiconductor device, such as a MOSFET, the on-resistance is mainly defined by the ohmic resistance of the drift region 13, where the ohmic resistance of the drift region 13 decreases as the doping concentration of the drift region 13 increases.

Thus, in the transistor device of FIGS. 1A to 1F, when implemented as an enhancement MOSFET, the source region 11 not only provides charge carriers when the transistor device is in the on-state, but the source region 11 additionally acts as a field electrode that compensates charge carriers in the drift region 11 when the transistor device is in the off-state. Thus, the transistor device can be implemented with a low-on resistance (a relatively high doping concentration of the drift region 13) but, nevertheless, with a relatively high voltage blocking capability. The absolute value of the voltage blocking capability is, inter alia, dependent on a length L of the drift region 13 in the vertical direction z. According to one embodiment, the length L of the drift region 13 is greater than 0.15 micrometers (μm), e.g., between 0.15 μm and 5 μm. The doping concentration of the drift region is, e.g. selected from a range of between 5E15 cm⁻³ and 1E19 cm⁻³. A thickness D of the dielectric layer 31, which is a dimension of a dielectric layer 31 in the first lateral direction x, is selected such that the dielectric layer 31 is capable of withstanding the voltage between the source region 11 and the drift region 13 when the transistor device is in the off-state. According to one embodiment, the thickness D of the dielectric layer 31 is below 300 nanometers (nm) or even below 100 nanometers. E.g., the thickness D is between 50 nm and 150 nm. Dependent on the specific value of the parameters explained before, in particular the length L and the doping concentration of the drift region 13, a voltage blocking capability of between 5V and several 10V, up to 150V can be obtained. The doping concentration of the drain region 14 is higher than the doping concentration of the drift region 13. According to one embodiment, the doping concentration of the drain region 14 is higher than 5E18 cm⁻³, or even higher than 1E19 cm⁻³. The drift region 13 may have a gradient of the doping concentration such that the doping concentration decreases in the direction of the body region 12. The gradient of the doping concentration influences the distribution of the electric field in the drift region 13 and is adjusted such that a maximum electric field strength can occur in the drift region 13 when the transistor device is in the off-state. The maximum electric field strength is dependent on the type of semiconductor material of the drift region and is about 3E5 μm in silicon. According to one embodiment, the doping concentration of the source region 11 is higher than 5E18 cm⁻³, or even higher than 1E19 cm⁻³.

The doping concentration of the body region 12 may be different in different types of transistor devices. For example, in an enhancement transistor device the doping concentration may be about 1E16 cm⁻³, or less, in a depletion transistor the doping concentration of the body region 12 may be higher, such as between 5E16 cm⁻³ and 1E18 cm⁻³.

Referring to FIGS. 1A, 1B and 1D to 1F, the gate electrode 21 (the position of which is illustrated in dashed lines in FIG. 1B) may overlap the source region 11 and the drift region 13. Especially, when the transistor device is implemented as a normally-off transistor device, a slight overlap of the gate electrode 21 over the source region 11 and the drift region 13 may ensure that a conducting channel can be generated in the body region 12 between the source region 11 and the drift region 13 when the transistor device is in the on-state. But this is not mandatory, as with low doping of the body region 12, also the functionality of a normally-off transistor device can be achieved with an underlap on the drain side. For a normally-on device, the gate electrode 21 should be positioned such that the gate electrode 21 may safely interrupt the conducting channel in the body region 12 between the source region 11 and the drift region 13 when the normally-on device is in the off-state.

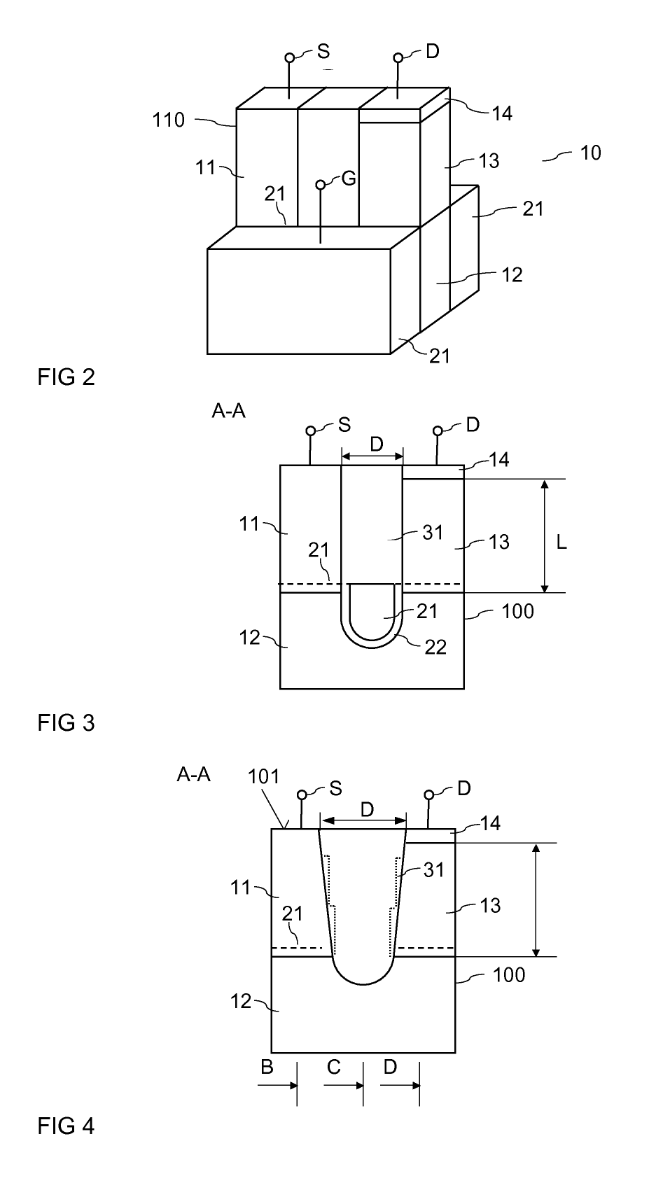

Different possible modifications of the transistor device of FIGS. 1A to 1F are explained with reference to FIGS. 2 to 5 below. These figures illustrate one of the different views explained with reference to FIGS. 1A to 1F below.

Referring to FIG. 2, that shows a perspective view of one transistor cell 10, the transistor device can be implemented as a junction FET (Junction Field-Effect Transistor) JFET. In this case, the gate electrode 21 adjoins the body region 12, so that there is no dielectric insulation between the body region 12 and the gate electrode 21. The gate electrode 21 includes a semiconductor material of a doping type complementary to the doping type of the body region 12, so that the gate electrode 21 (which may also be referred to as gate region in this case) and the body region 12 form a pn-junction. At least in those regions where the gate electrode 21 adjoins the body region 12, the gate electrode 21 may include a monocrystalline semiconductor material. The transistor device may be implemented as an n-type or p-type JFET. In the first case, the source region 11, the body region 12, the drift region 13 and the drain region 14 are n-doped. In the second case, these device regions are p-doped. The transistor device, when implemented as a JFET, can be operated like a conventional JFET.

Referring to FIG. 3, a section of the gate electrode 21 may be arranged in the trench with the dielectric layer 31 between the dielectric layer 31 and the body region 12. Like outside the trench, the gate electrode 21 may be dielectrically insulated from the body region 12 by a section of the gate dielectric 22 in the trench. The gate dielectric 22 is omitted when the transistor device is implemented as a JFET. The gate electrode section in the trench electrically connects those sections of the gate electrode 21 that are located on the opposite sidewalls 102, 103 of the semiconductor fin 110.

Referring to a further embodiment illustrated in FIG. 4, a thickness D of the dielectric layer 31 varies such that the thickness D decreases towards the body region 12. Thus, the thickness D of the dielectric layer 31 is smaller close to the body region 12 than more distant to the body region 12. This takes into account that, when a transistor device is in the off-state and when a positive voltage is applied between the drain and source terminals D, S, the electrical potential in the drift region 13 increases towards the drain region 14 and decreases towards the body region 12, respectively. Thus, a voltage between the drift region 13 and the source region 11 (that has an approximately constant electrical potential) is higher in regions close to the drain region 14, so that a thicker dielectric layer 31 is required in these regions, while the voltage is lower in regions close to the body region 12. The width W of the dielectric layer 31 may decrease continuously (as illustrated in solid lines in FIG. 4). According to a further embodiment, the thickness varies in discrete steps (as illustrated in dotted lines in FIG. 4).

FIG. 5 shows a vertical cross-sectional view of a transistor cell 10 that additionally includes a body contact region 15 that is connected to the body region 12. The body contact region 15 is adjacent the source region 11 and is dielectrically insulated from the source region 11 by a further dielectric layer 32. According to one embodiment, the body contact region 15 is electrically connected to the source terminal S (as illustrated in FIG. 5). The body contact region 15 may include a monocrystalline or polycrystalline semiconductor material of a doping type complementary to the doping type of the source region 11.

In case the transistor device is implemented as an enhancement MOSFET, the body contact region 15 has the same doping type as the body region 12 and electrically connects the body region 12 to the source terminal S. In this case, the pn-junction between the body region 12 and the drift region 13 forms an internal diode (body diode) between the source and drain terminals S, D. The same applies when the transistor device is implemented as a depletion MOSFET with a body region 12 of the same doping type as the source region 11, or with at least one channel region 12′ of the same doping type as the source region 11. When the depletion MOSFET is in an off-state, the body region 12 can be inverted (p-conducting) and is directly connected to the source terminal S via the p-doped body contact 15.

In case the transistor device is implemented as a depletion transistor with a body region 12 of the same doping type as the source region 11 or as a JFET, a pn-junction is formed in the off-state between the body contact region 15 over the body region 12 and the drain region 14. This pn-junction forms an internal diode (body diode) between the source and drain terminals S, D

Referring to FIG. 5, the body contact region 15 may be arranged adjacent the source region 11 on a side facing away from the dielectric layer 31 and the drift region 13. The features explained with reference to FIGS. 2 to 5 may be combined, so that one or more of the features explained with reference to FIGS. 2 to 5 may be implemented in one transistor device.

FIG. 6 illustrates a vertical cross-sectional view of a transistor device according to a further embodiment. FIG. 6 illustrates a vertical cross-sectional view of the semiconductor fin 110, where the position of the gate electrode 21 along the sidewalls of the semiconductor fin 110 is illustrated in dashed lines. The transistor device of FIG. 6 includes a plurality of transistor cells with source, body, drift and drain regions 11, 12, 13, 14 implemented in one semiconductor fin 110. The transistor cells 10 of FIG. 6 are implemented as explained with reference to FIG. 1. However, this is only an example. The individual transistor cells 10 could be implemented in accordance with any of the further embodiments explained hereinbefore as well. Referring to FIG. 6, the individual transistor cells 10 share one body region 12 and one gate electrode 21 (located on opposite sides of the semiconductor fin 110 and optionally in the trenches adjacent the body region 12). Further, two adjacent transistor cells 10 share one source region 11, and two transistor cells 10 share one drift region 13 and one drain region 14. That is, the source regions 11 and drift regions 13 are arranged alternatingly between two adjacent dielectric layers 31. The individual source regions 11 are connected to the source terminal S, while the individual drain regions 14 are connected to the drain terminal D, so that the individual transistor cells 10 are connected in parallel. The gate terminal G is out view in the embodiment of FIG. 6. The current rating of the transistor device increases as the number of transistor cells 10 connected in parallel increases.

FIG. 7 illustrates a modification of the transistor device of FIG. 6. The transistor device of FIG. 7 includes a body contact region 15 that is electrically connected to the body region 12 and to the source terminal S in the present embodiment. Since the individual transistor cells 10 share one body region 12, one body contact region 15 is sufficient to electrically connect the body region 12 of one semiconductor fin 110 to the source terminal S. Of course, more than one body contact region 15 may be implemented in one semiconductor fin 110 as well.

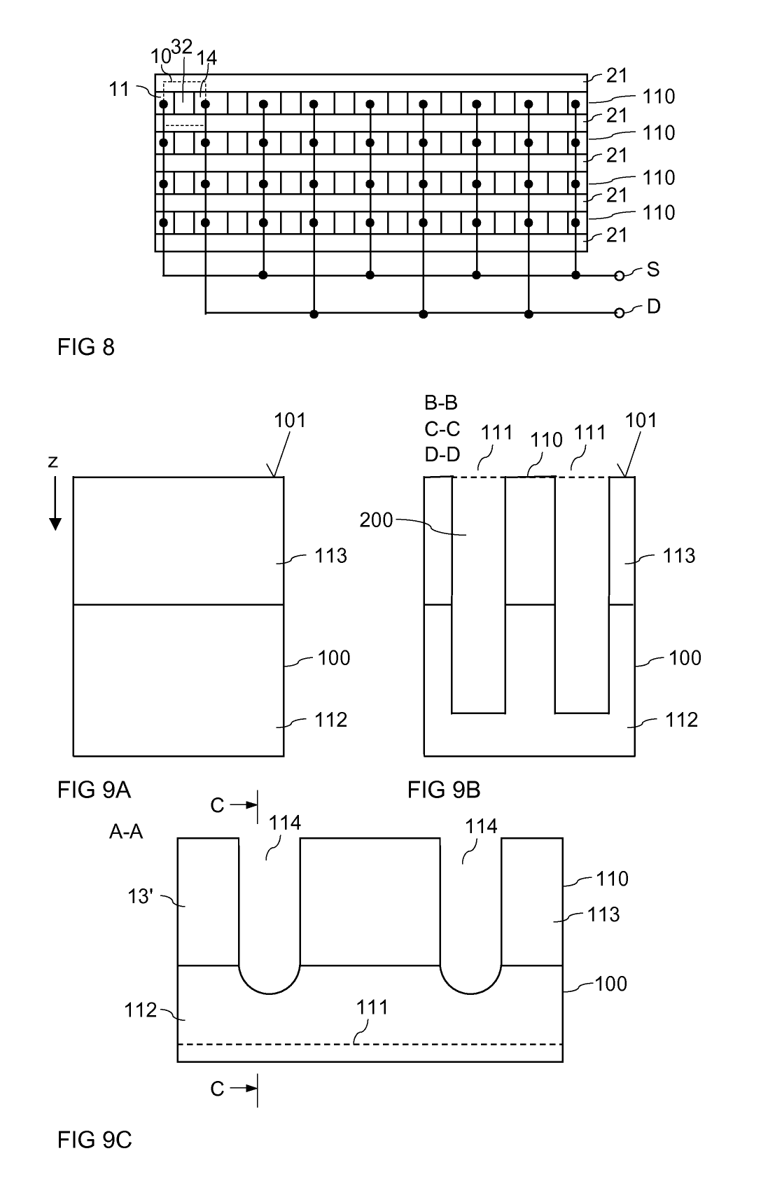

FIG. 8 illustrates a top view of a transistor device that includes a plurality of semiconductor fins 110, with each semiconductor fin 110 including a plurality of transistor cells 10. The individual semiconductor fins 110 are essentially parallel, wherein the gate electrodes 21 are arranged between the individual semiconductor fins 110. Optional gate dielectrics are not illustrated in FIG. 8. The source regions 11 of the individual transistor cells 10 are electrically connected to a source terminal S, the drain terminals 14 are electrically connected to a drain terminal D, and the individual gate electrodes 21 are electrically connected to a common gate terminal G. Thus, the individual transistor cells 10 are connected in parallel.

The individual transistor cells 10 in the transistor device of FIG. 8 may be implemented in accordance with one of the embodiments explained before. The current rating of the transistor device increases with an increasing number of transistor cells 10. According to one embodiment, the transistor device includes several 10, several 100, several 1000 or even several millions of transistor cells 10 connected in parallel.

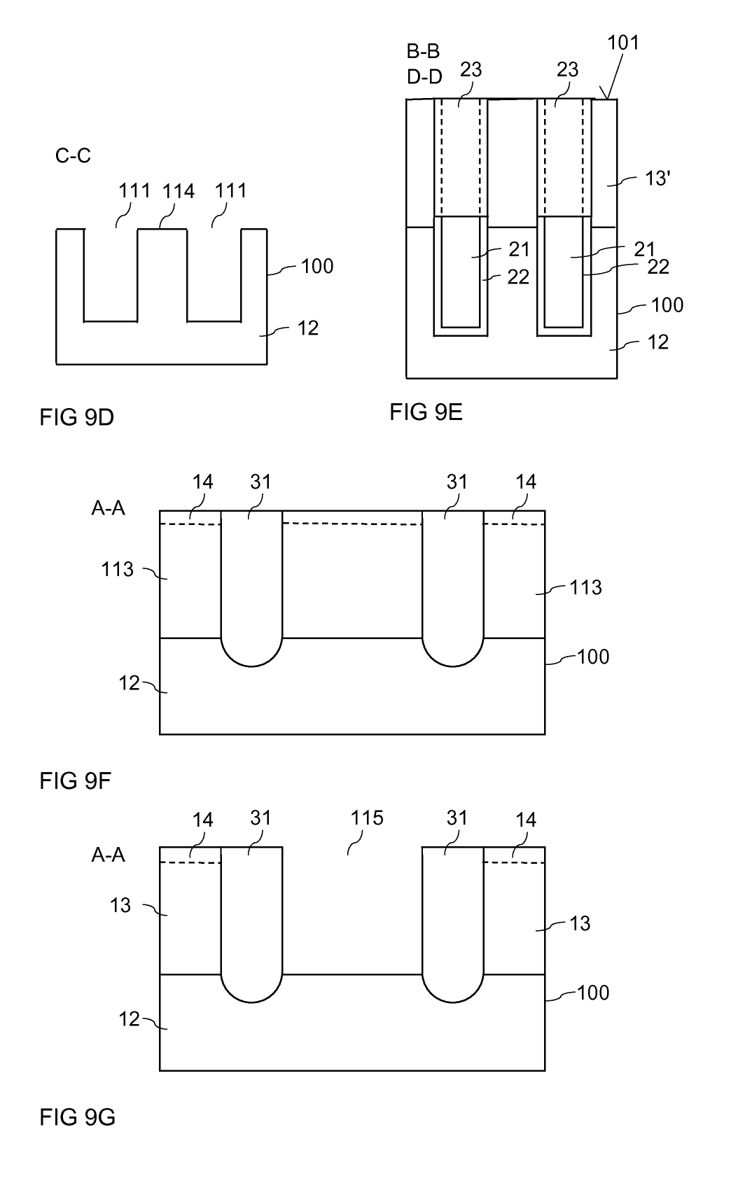

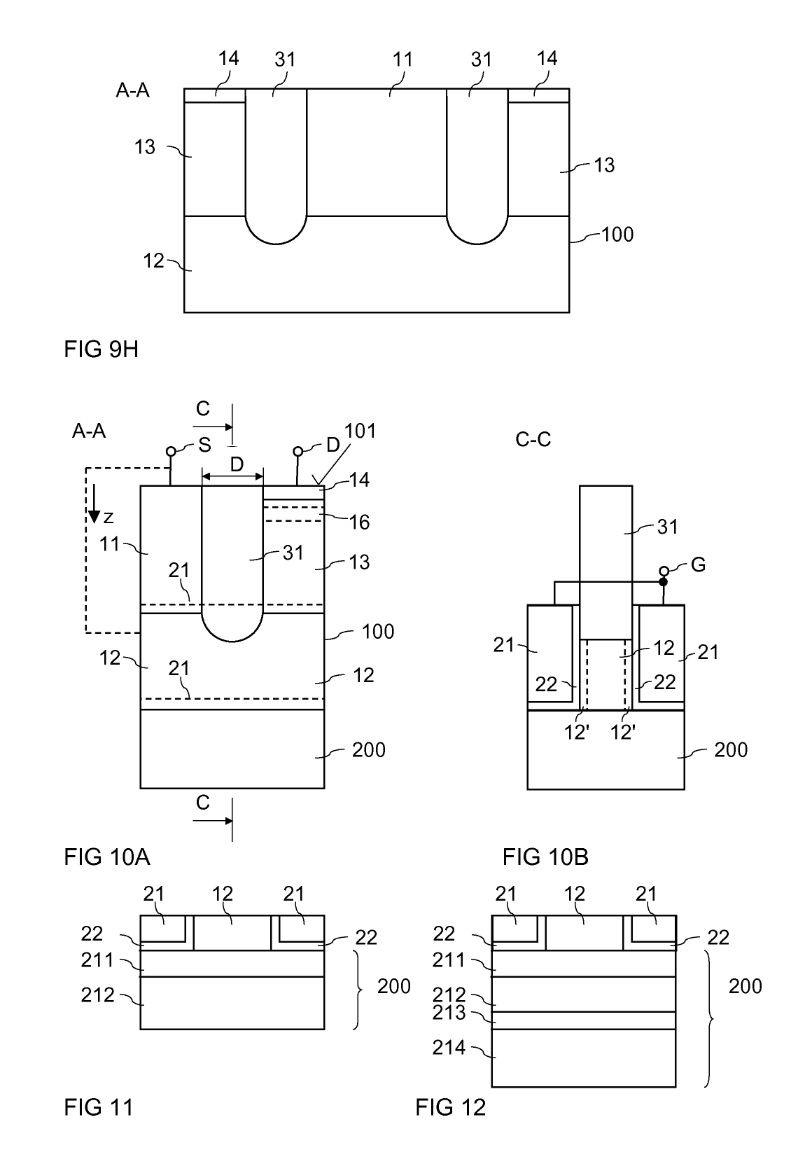

One embodiment of a method for producing two adjacent transistor cells that share one source region 11 is explained with reference to FIGS. 9A to 9H below. The individual figures show vertical cross-sectional views of a semiconductor body 100 during steps of the method.

Referring to FIG. 9B the method includes providing a semiconductor body 100 with at least one semiconductor fin 110. Referring to FIGS. 9A and 9B, providing the semiconductor body 100 with the at least one semiconductor fin 110 may include etching essentially parallel trenches 111 from a first surface 101 of the semiconductor body 100 into the semiconductor body 100. The semiconductor fin 110 is the semiconductor region remaining between two parallel trenches 111. In general, the number of parallel trenches 111 defines the number of semiconductor fins 110 in the semiconductor body 100, where forming of n, with n≧2, parallel trenches 111 results in n−1 semiconductor fins 110.

Referring to FIGS. 9A and 9B, the semiconductor body 100 includes two different semiconductor layers, namely a first semiconductor layer 112 having a doping concentration corresponding to the doping concentration of the body region 12 in the finished transistor device, and a second semiconductor layer 113 having a doping concentration corresponding to the doping concentration of the drift region 13 in the finished transistor device. The semiconductor body 100 with the two different semiconductor layers 112, 113 can be produced in a conventional way.

According to one embodiment, the second semiconductor layer 113 is an epitaxial layer grown on the first semiconductor layer 112. In this case, the first semiconductor layer 112 may be a semiconductor substrate having a basic doping concentration corresponding to the doping concentration of the body region 12, while the doping concentration of the second semiconductor layer 113 and a thickness of the second semiconductor layer 113 in the vertical direction z can be adjusted during the epitaxial growth process. The thickness of the second semiconductor layer 113 defines the length of the drift region (region 13 in FIGS. 1A to 1F and 2 to 5), where the length L of the drift region 13 corresponds to the thickness of the semiconductor layer 113 minus a dimension of the drain region 14 in the vertical direction z.

According to a further embodiment, a semiconductor substrate is provided that includes a basic doping corresponding to the doping concentration of the body region 12. The second semiconductor layer 113 is produced in this substrate using an implantation and/or diffusion process. The first semiconductor layer 112 corresponds to those regions of the substrate that are not doped in the doping process.

According to one embodiment, the second semiconductor layer 113 has an essentially constant doping concentration. According to a further embodiment, the doping concentration in the second semiconductor layer 113 decreases towards the first semiconductor layer 112, so that there is a negative gradient of the doping concentration in the second semiconductor layer 113 when proceeding from the first surface 101 in the vertical direction z. Such a gradient may be obtained with both of the methods for providing the semiconductor body 100 explained before.

Referring to FIG. 9C, that shows a vertical cross-sectional view of the semiconductor fin 110 in a section plane corresponding to section plane A-A explained before, two trenches 114 are formed in the semiconductor fin 110 such that these two trenches 114 extend from the first surface 101 through the second semiconductor layer 113 to or into the first semiconductor layer 112. These further trenches 114 do not extend as deep into the semiconductor body 100 as the trenches 111 that define the semiconductor fin 110. The bottom of the trenches 111 defining the semiconductor fin 110 is illustrated in dashed lines in FIG. 9C. The trenches 111 defining the semiconductor fin 110 and the further trenches 114 in the semiconductor fin 110 may be produced using conventional techniques, such as etching techniques using etch masks. According to one embodiment, the trenches 111 defining the semiconductor fin 110 are filled with a protection layer, such as a nitride or an oxide, before etching the trenches 114 in the semiconductor fin 110.

FIG. 9D illustrates a vertical cross sectional view in a section plane C-C that cuts through one of the trenches 114. As can be seen from FIG. 9D, the trenches 111 defining the semiconductor fin 110 extend deeper into the semiconductor body 100 than the trenches 114 in the semiconductor fin 110.

In next method steps, the result of which is illustrated in FIGS. 9E and 9F, the gate electrode 21 and the optional gate dielectric 22 is formed in the trenches 111 defining the semiconductor fin 110, and the dielectric layer 31 is formed in the trenches 112 in the semiconductor fin 110. These method steps may include forming the gate dielectric 22 in the trenches 111 at least adjacent the first semiconductor layer 112. Forming the gate dielectric 22 may include a thermal oxidation process. Subsequently, the gate electrode 21 is formed on the gate dielectric 22 adjacent the first semiconductor layer 112 (that forms the body region 12 in the finished transistor device). A width of the trenches 111 defining the semiconductor fin 110 is more than twice the thickness of the gate dielectric 22, so that the gate dielectric 22 does not completely fill these trenches 111, and so that the gate electrode 21 can be formed on the gate dielectric 22. According to one embodiment, a width D of the trenches 114 in the semiconductor fin 110 is less than twice the thickness of the gate dielectric 22. In this case, the gate dielectric 22 completely fills these trenches 114, forming the dielectric layer 31 in these trenches.

According to a further embodiment, a width W of the trenches 114 in the semiconductor fin 110 is more than twice the thickness of the gate dielectric 22. In this case, a residual trench remains after forming the gate dielectric 22, and the gate electrode 21 is formed in a lower region of these trenches, as illustrated in FIG. 3.

The step of forming the gate dielectric 22 is omitted when the transistor device is implemented as a JFET.

After the optional gate dielectric 22 and the gate electrode 21 have been formed, the trenches 111 are filled with a dielectric material 23 (see FIG. 9E). The dielectric material 23 may include the gate dielectric material (illustrated in dashed lines in FIG. 9E) and an additional dielectric and/or insulation material filling the trenches 111. According to one embodiment, a section of the gate electrode 21 extends to the surface 101, where the gate electrode 21 may be connected to the gate terminal G. However, such section of the gate electrode 21 extending to the surface 101 is not explicitly illustrated in the figures.

In case the gate dielectric 22 does not completely fill the trenches 112 in the semiconductor fin 110, these trenches 112 are completely filled when forming the dielectric layer 23 in the other trenches 111.

Referring to FIG. 9G, the second semiconductor layer 113 is removed between the dielectric layers 31 down to the first semiconductor layer 112 so as to form a trench 115 in the second semiconductor layer 113 optionally by means of a masking layer. Then, referring to FIG. 9H, the source region 11 is formed in this trench 115 between the dielectric layers 31. Forming the source region 11 may include filling the trench with a doped polycrystalline semiconductor material, or epitaxially growing a doped semiconductor material, that forms the source region 11, on the first semiconductor layer 112 in the trench 115 between the dielectric layers 31.

Referring to FIG. 9H, remaining sections of the second semiconductor layer 113 form the drift region 13, and the first semiconductor layer 112 forms the body region 12 of the transistor device. Further, the drain region 14 is formed in the drift region 13 in the region of the first surface 101. Forming the drain region 14 may include at least one of an implantation and diffusion process. According to one embodiment, the drain region 14 is formed before producing the trench 113 (as illustrated in dashed lines in FIGS. 9F and 9G). However, it is also possible to form the drain region 14 after forming the source region 11 in the trench 115 between the dielectric layers 31.

Each of the transistor devices explained before may include a substrate that carries the device structures explained before. This is explained in greater detail with reference to FIGS. 10A and 10B below.

FIGS. 10A and 10B show vertical cross-sectional views of one transistor cell in section planes corresponding to section planes A-A and C-C explained before. Just for illustration purposes, the transistor cell of FIGS. 10A and 10B corresponds to the transistor explained with reference to FIGS. 1A to 1F before. However, any other type of transistor cell explained before may be used as well.

Referring to FIGS. 10A and 10B, a substrate 200 is adjacent the body region 12 and the gate electrode 21 in the vertical direction z. While the body region 12 adjoins the substrate 200, the gate electrode 21 may be dielectrically insulated from the substrate 200 by the gate dielectric 22 or another dielectric layer. The presence of a dielectric layer between the gate electrode 21 and the substrate 200 is dependent on the type of substrate 200. Such dielectric layer may be omitted when the substrate 200 itself is a dielectric layer or includes a dielectric layer as an uppermost layer adjoining the body region 12.

The substrate 200 can be implemented in many different ways. Dependent on the specific implementation, the substrate 200 may only serve as a carrier for carrying the at least one transistor cell or may have an electric function itself.

According to a first embodiment, the substrate 200 is a semiconductor substrate of the same doping type as the body region 12. In this case, the substrate 200 may be connected to the source terminal S and may serve to connect the body region 12 to the source terminal.

According to a second embodiment, the substrate 200 is a semiconductor substrate of the same doping type as the source region 11 and is electrically connected to the source terminal S. In this case, the substrate 200 acts as a further source region of the transistor device 100, wherein the body region 12 is arranged between source region 11 and the further source region formed by the substrate 200.

According to a third embodiment, the substrate 200 is a dielectric layer or includes a dielectric layer as an uppermost layer adjoining the body region 12 and the gate electrode 21. In this case, the substrate 200 only serves as a carrier.

According to a fourth embodiment illustrated in FIG. 11, the substrate 200 includes two semiconductor layers, namely a first layer 211 of the same doping type as the source region 11 and adjoining the source region 12, and a second layer 212 adjoining the first layer 211 and doped complementary so that a pn-junction is formed between the first and second layers 211, 212. The first layer 211 may be connected to the source terminal S and may form a further source region. The pn-junction provides a junction isolation between the body regions 12 of individual transistor cells if several transistor cells are formed on one substrate.

A fifth embodiment is based on the embodiment of FIG. 12 and additionally includes a third semiconductor layer 214, a dielectric layer 213 adjoining the third layer 214 on one side and the second semiconductor layer 212 on the other side.

According to yet another embodiment, which is a modification of the embodiment of FIG. 12, the first semiconductor layer 211 or the second semiconductor layer 212 is omitted. In the first case, the second layer 212 adjoins the body region 12 and may serve to connect the body region 12 to the source terminal. In the second case, the first layer 211 adjoins the dielectric layer 213.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device comprising at least one transistor cell, the at least one transistor cell comprising:
a semiconductor fin;
a source region, a drain region, a drift region and a body region in the semiconductor fin, the body region arranged adjacent the source region and the drift region in a first direction of the semiconductor fin, the source region arranged adjacent the drift region in a second direction of the semiconductor fin and dielectrically insulated from the drift region by a dielectric layer, the drift region arranged adjacent the drain region in the first direction and having a doping concentration lower than a doping concentration of the drain region; and
a gate electrode adjacent the body region in a third direction of the semiconductor fin.

2. The transistor device of claim 1, wherein the gate electrode is dielectrically insulated from the body region by a gate dielectric.

3. The transistor device of claim 1, wherein the gate electrode adjoins the body region.

4. The transistor device of claim 1, wherein the at least one transistor cell further comprises:
two gate electrodes adjacent the body region on opposite sides of the semiconductor fin.

5. The transistor device of claim 1, wherein the gate electrode is adjacent the body region on opposite sides of the semiconductor fin.

6. The transistor device of claim 1, wherein the gate electrode further comprises a gate electrode section in the semiconductor fin between the body region and the dielectric layer.

7. The transistor device of claim 1 wherein a doping concentration of the source region is higher than 5E18 cm⁻³, or higher than 1E19 cm⁻³.

8. The transistor device of claim 7, wherein the source region comprises one of a monocrystalline and a polycrystalline semiconductor material.

9. The transistor device of claim 1, wherein a doping concentration of the drift region is selected from a range of between 5E15 cm⁻³ and 1E19 cm⁻³.

10. The transistor device of claim 1, wherein a doping concentration of the drain region is higher than 5E18 cm⁻³, or higher than 1E19 cm⁻³.

11. The transistor device of claim 1, wherein the source region, the body region, the drift region and the drain region have the same doping type.

12. The transistor device of claim 1, wherein the source region and the drift region have a first doping type, and the body region has a second doping type complementary to the first doping type.

13. The transistor device of claim 12, wherein the drain region has one of the first doping type and the second doping type.

14. The transistor device of claim 1, wherein a length of the drift region in the first direction is above 0.15 micrometers.

15. The transistor device of claim 1, wherein a distance of the source region and the drift region in the second direction is below 300 nanometers, or below 100 nanometers.

16. The transistor device of claim 1, wherein the dielectric layer between the source region and the drift region has a varying width such that the width decreases towards the body region.

17. The transistor device of claim 1, further comprising:
a body contact region adjoining the body region; and
wherein the body contact region is arranged adjacent the source region in the second direction and dielectrically insulated from the source region by a further dielectric layer.

18. The transistor device of claim 1, further comprising a plurality of transistor cells connected in parallel,
wherein the plurality of transistor cells share the body region,
wherein two adjacent transistor cells share one drain region, and
wherein two adjacent transistor cells share one source region.

19. The transistor device of claim 18, further comprising a plurality of semiconductor fins, each semiconductor fin comprising a plurality of the transistor cells.

20. The transistor device of claim 1, further comprising:
a substrate adjoining the body region in the first direction.

21. A method for producing a transistor device, comprising:
providing a semiconductor body comprising at least one semiconductor fin, the at least one semiconductor fin comprising a drift region and a body region adjoining the first region in a first direction of the semiconductor fin;
forming at least two trenches that are distant in a second direction of the semiconductor fin and that each extend through the drift region to or into the body region;
forming a gate electrode adjacent the body region of the semiconductor fin on at least one side of the semiconductor fin;
forming dielectric layers in the at least two trenches;
removing the drift region between the at least two trenches and forming a source region between the at least two trenches where the drift region was removed; and
forming a drain region in remaining sections of the drift region and in the region of a surface of the semiconductor fin.

22. The method of claim 21, wherein forming the source region comprises forming one of a monocrystalline and a polycrystalline semiconductor material on the body region.

23. The method of claim 21, wherein providing the semiconductor body comprising the at least one semiconductor fin comprises forming two substantially parallel trenches in the semiconductor body.

24. The method of claim 21, further comprising:
forming a gate dielectric on the body region before forming the gate electrode.

25. The method of claim 21, further comprising:
forming the gate electrode such that the gate electrode adjoins the body region.
